(19) United States
(12) Patent Application Publication
(10) Pub. No.: US 2025/0238563 A1
(43) Pub. Date: Jul. 24, 2025

(54) METHOD AND SYSTEM FOR AN END-TO-END TWO-DIMENSIONAL AND THREE-DIMENSIONAL GEOLOGICAL MODELING

(71) Applicants: KING FAHD UNIVERSITY OF PETROLEUM AND MINERALS, Dhahran (SA); Saudi Data and Artificial Intelligence Authority (SDAIA), Riyadh (SA)

(72) Inventors: Lundi KUSUMA, Dhahran (SA); Ardiansyah Ibnu KOESHIDAYATULLAH, Dhahran (SA); Sanlinn Isma'il Ebrahim KAKA, Dhahran (SA); Khalid Abdulsamad Hasan AL-RAMADAN, Dhahran (SA)

(73) Assignees: KING FAHD UNIVERSITY OF PETROLEUM AND MINERALS, Dhahran (SA); Saudi Data and Artificial Intelligence Authority (SDAIA), Riyadh (SA)

(21) Appl. No.: 18/420,295

(22) Filed: Jan. 23, 2024

(51) Int. Cl. G06F 30/13

(52) U.S. Cl. CPC G06F 30/13

(57) ABSTRACT

A method and system for an end-to-end two-dimensional (2D) and three-dimensional (3D) geological modeling includes combining and converting a one-dimensional (1D) dataset to obtain a 1D combined dataset. The method further includes pre-processing the 1D combined dataset, and processing the 1D combined dataset based on a first prediction algorithm to obtain a 1D prepared dataset and/or generating a 3D grid based on a 2D subsurface data and a 3D data in the absence of a seismic data (e.g., 3D seismic cube, 2D seismic data). The method may include sampling the 1D prepared dataset along a well bore into the 3D grid to obtain a 3D structured dataset and/or generating a 2D geological model from the 3D structured dataset by a second prediction algorithm, and generating a 3D geological model from the 3D structured dataset and the 2D geological model by a hybrid algorithm.

### BACKGROUND

### Technical Field

The present disclosure is directed to the field of geological modeling, specifically to a method and system for integrating machine learning and geostatistics in creating end-to-end two-dimensional (2D) and three-dimensional (3D) geological models.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly nor impliedly admitted as prior art against the present invention.

Geological modeling, as a tool in earth science, especially in the oil and gas industry, has traditionally utilized seismic data. This method involves generating seismic waves and interpreting their reflections from subsurface structures to create geological models. These models are utilized for understanding subsurface geology and identifying potential areas for resource extraction. Over the years, advancements in this field have led to the development of sophisticated computational models and data processing techniques. These advancements have enabled geologists and engineers to interpret seismic signals with greater accuracy, thereby enhancing the understanding of complex subsurface geological structures.

Despite the value of seismic methods in geological modeling, they present significant challenges. The primary issue is the cost and logistical complexity of acquiring seismic data. Conducting seismic surveys, especially in remote or environmentally sensitive areas, can be prohibitively expensive and involve intricate planning and execution. Another challenge is the inherent limitation in the resolution of seismic data. While seismic waves can penetrate deep into the Earth's crust, they often fail to provide a clear and detailed picture of complex geological formations. This limitation can lead to inaccuracies in the models, which are particularly problematic in areas with intricate geological structures.

Given the limitations of current methods in geological modeling, there is a need for more accessible, cost-effective solution that can leverage existing, less expensive data sources, such as well logs, to create accurate geological models. Accordingly, it is one object of the present disclosure to provide a method and a system for an end-to-end two-dimensional (2D) and three-dimensional (3D) geological modeling that combines the predictive power of machine learning with the spatial analysis capabilities of geostatistics.

### SUMMARY

In an exemplary embodiment, a computer implemented method for an end-to-end two-dimensional (2D) and three-dimensional (3D) geological modeling is provided. The method comprises combining and converting a one-dimensional (1D) dataset to obtain a 1D combined dataset. Herein, the 1D dataset comprises a well header, a trajectory, a well log data, and a well picks. The method further comprises pre-processing the 1D combined dataset. The method further comprises processing the 1D combined dataset based on a first prediction algorithm to obtain a 1D prepared dataset. The method further comprises generating a 3D grid based on a 2D subsurface data and a 3D data in the absence of a seismic data (e.g., 3D seismic cube, 2D seismic data). The method further comprises sampling the 1D prepared dataset along a well bore into the 3D grid to obtain a 3D structured dataset having a spatial information. The method further comprises generating a 2D geological model from the 3D structured dataset by a second prediction algorithm. The method further comprises generating a 3D geological model from the 3D structured dataset and the 2D geological model by a hybrid algorithm. Herein, the hybrid algorithm comprises a third prediction algorithm and a geostatistics algorithm.

In some embodiments, the well log data is selected from the group consisting of a continuous basic log, an interpreted continuous log, an interpreted discrete log, and a combination thereof.

In some embodiments, the pre-processing step further comprises: analyzing the 1D combined dataset with an exploratory data analysis to obtain descriptive statistics and characteristics of the well log data and a relationship within the well log data; cleaning the 1D combined dataset to mitigate missing data or outliers; rescaling and transforming the 1D combined dataset for homogeneity; and executing a feature ranking.

In some embodiments, the processing step further comprises: splitting the 1D combined dataset into train data, test data, and blind well data; training the first prediction algorithm with the train data; evaluating the first prediction algorithm by performing a prediction with the test data; tuning a first setting of the first prediction algorithm based on an evaluation; and obtaining the 1D prepared dataset using a tuned first prediction algorithm.

In some embodiments, the well log data is continuous. Herein, the first prediction algorithm is selected from a support vector machine, a ridge regression, an extreme gradient boosting, an artificial neural network, a deep neural network, and a long short-term memory.

In some embodiments, the well log data is discrete. Herein, the first prediction algorithm is a discrete supervised prediction selected from the group consisting of a random forest, an artificial neural network, a deep neural network, and the long short-term memory.

In some embodiments, the tuning step further comprises: clustering the 1D combined dataset with a sequent hierarchical clustering algorithm; determining a number of clusters based on an elbow method; creating a discrete unsupervised clustering; evaluating the discrete unsupervised clustering; tuning a second setting of the sequent hierarchical clustering algorithm; and integrating the discrete unsupervised clustering to the first prediction algorithm.

In some embodiments, the generating the 2D geological model step further comprises: slicing the 3D structured dataset in a vertical layer; training the second prediction algorithm using a sliced 3D structured dataset; evaluating the second prediction algorithm; tuning a third setting of the second prediction algorithm; and generating the 2D geological model.

In some embodiments, the generating the 3D geological model step further comprises: training the third prediction algorithm using the 3D structured dataset; evaluating the third prediction algorithm; tuning a fourth setting of the third prediction algorithm; generating a 3D facies trend by the third prediction algorithm; integrating the 3D facies trend into the geostatistics algorithm to create the hybrid algorithm; evaluating the hybrid algorithm; and generating the 3D geological model based on the hybrid algorithm. Herein, the 3D geological model is constrained by a hybrid facies.

In some embodiments, the third prediction algorithm is selected from the group consisting of a support vector machine, a k-nearest neighbor, and a gaussian process.

In some embodiments, the geostatistics algorithm is a sequential indicator simulation.

In some embodiments, the well log data includes a geological facies and a measured petrophysical property. Herein, a first 3D geological model of the geological facies is generated before a second 3D geological model of the measured petrophysical property.

In another exemplary embodiment, a system for an end-to-end two-dimensional (2D) and three-dimensional (3D) geological modeling is provided. The system comprises a data receiver configured to collect a one-dimensional (1D) data from a logging device. The system further comprises a memory to store a program instruction. The system comprises a processor coupled to the memory and the data receiver. The processor is configured to receive the 1D data from the data receiver. Herein, the 1D dataset comprises a well header, a trajectory, a well log data, and a well picks. The processor is further configured to execute the program instruction. Herein, the program instruction comprises: combining and converting the 1D dataset to obtain a 1D combined dataset; pre-processing the 1D combined dataset; processing the 1D combined dataset based on a first prediction algorithm to obtain a 1D prepared dataset; generating a 3D grid based on a 2D subsurface data and a 3D data in the absence of a seismic data (e.g., 3D seismic cube, 2D seismic data); sampling the 1D prepared dataset along a well bore into the 3D grid to obtain a 3D structured dataset having a spatial information; and generating a 2D geological model from the 3D structured dataset by a second prediction algorithm; and generating a 3D geological model from the 3D structured dataset and the 2D geological model by a hybrid algorithm. Herein, the hybrid algorithm comprises a third prediction algorithm and a geostatistics algorithm.

In some embodiments, the pre-processing step further comprises: analyzing the 1D combined dataset with an exploratory data analysis to obtain descriptive statistics and characteristics of the well log data and a relationship within the well log data; cleaning the 1D combined dataset to mitigate missing data or outliers; rescaling and transforming the 1D combined dataset for homogeneity; and executing a feature ranking.

In some embodiments, the processing step further comprises: splitting the 1D combined dataset into train data, test data, and blind well data; training the first prediction algorithm with the train data; evaluating the first prediction algorithm by performing a prediction with the test data; tuning a first setting of the first prediction algorithm based on an evaluation; and obtaining the 1D prepared dataset using a tuned first prediction algorithm.

In some embodiments, the well log data is continuous. Herein, the first prediction algorithm is selected from a support vector machine, a ridge regression, an extreme gradient boosting, an artificial neural network, a deep neural network, and a long short-term memory.

In some embodiments, the well log data is discrete. Herein, the first prediction algorithm is a discrete supervised prediction selected from the group consisting of a random forest, an artificial neural network, a deep neural network, and the long short-term memory.

In some embodiments, the tuning step further comprises: clustering the 1D combined dataset with a sequent hierarchical clustering algorithm; determining a number of clusters based on an elbow method; creating a discrete unsupervised clustering; evaluating the discrete unsupervised clustering; tuning a second setting of the sequent hierarchical clustering algorithm; and integrating the discrete unsupervised clustering to the first prediction algorithm.

In some embodiments, the generating the 2D geological model step further comprises: slicing the 3D structured dataset in a vertical layer; training the second prediction algorithm using a sliced 3D structured dataset; evaluating the second prediction algorithm; tuning a third setting of the second prediction algorithm; and generating the 2D geological model.

In some embodiments, the generating the 3D geological model step further comprises: training the third prediction algorithm using the 3D structured dataset; evaluating the third prediction algorithm; tuning a fourth setting of the third prediction algorithm; generating a 3D facies trend by the third prediction algorithm; integrating the 3D facies trend into the geostatistics algorithm to create the hybrid algorithm; evaluating the hybrid algorithm; and generating the 3D geological model based on the hybrid algorithm. Herein, the 3D geological model is constrained by a hybrid facies.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is an exemplary flowchart of a computer implemented method for an end-to-end two-dimensional (2D) and three-dimensional (3D) geological modeling, according to certain embodiments.

FIG. 2 is an exemplary block diagram of a system for the end-to-end 2D and 3D geological modeling, according to certain embodiments.

FIG. 3 is an exemplary flowchart of a workflow for predicting subsurface geological structures, according to certain embodiments.

FIG. 4 is an exemplary flowchart of a workflow for a preparatory phase for machine learning (ML) in geological modeling, according to certain embodiments.

FIG. 5 is an exemplary flowchart of a workflow for one-dimensional (1D) ML well log prediction, according to certain embodiments.

FIG. 6 is an exemplary flowchart of a workflow for 2D or 3D ML spatial prediction, according to certain embodiments.

FIG. 7 is an exemplary illustration of a matrix for Exploratory data analysis (EDA) for ML, according to certain embodiments.

FIG. 8A is an exemplary illustration of a table showing precision, recall, f1-score, and support for each facies class, according to certain embodiments.

FIG. 8B is an exemplary illustration of a confusion matrix to visualize performance of a ML model, according to certain embodiments.

FIG. 8C is an exemplary illustration of a bar graph comparing actual and predicted facies at various depths, according to certain embodiments.

FIG. 9A is an exemplary illustration of an image depicting use of Support Vector Machine (SVM) ML trend for understanding facies distribution, according to certain embodiments.

FIG. 9B is an exemplary illustration of an image depicting use of Sequential Indicator Simulation (SIS) combined with ML to identify facies trends, according to certain embodiments.

FIG. 9C is an exemplary illustration of an image depicting use of Sequential Gaussian Simulation (SGS), constrained to facies, for modeling porosity, according to certain embodiments.

FIG. 10 is an illustration of a non-limiting example of details of computing hardware used in the computing system, according to certain embodiments.

FIG. 11 is an exemplary schematic diagram of a data processing system used within the computing system, according to certain embodiments.

FIG. 12 is an exemplary schematic diagram of a processor used with the computing system, according to certain embodiments.

FIG. 13 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspects of this disclosure are directed to a method and a system for an end-to-end two-dimensional (2D) and three-dimensional (3D) geological modeling. Machine learning (ML) algorithms are particularly powerful to identify hidden patterns and capture complex nonlinear relationships in data. In geosciences, subsurface reservoir characterizations have been the primary focus in applying AI technology due to the availability of huge volume datasets and the complexity of their characterization which can benefit from machine intelligence. In subsurface geological characterization, these studies can be categorized based on the data dimensions which are one dimension (1D), two dimensions (2D), and three dimensions (3D). Facies and porosity data are a few examples of datasets that can benefit from data-driven algorithms. Facies, which define different rock types and characteristics, and porosity, indicating the space within rocks that can hold fluids, are useful for understanding subsurface geology. Both facies and porosity hold a fundamental building block in the 3D geological modeling. The static petrophysical property is primarily controlled by geological facies. Both datasets are typically obtained from well log and core descriptions and measurements. The latter normally has limited availability and is very expensive to obtain. To perform such a characterization, these limited 1D facies and porosity data need to be propagated to all non-cored intervals and well data across 1D, 2D, and 3D spaces. Recent development of AI technology has allowed end-to-end geological modeling by using advanced ML algorithms.

The method and the system of the present disclosure leverage ML to extrapolate this sparse 1D data across multiple dimensions, providing a more detailed and cost-effective method for geological modeling. The proposed approach for end-to-end ML is as follows: (i) 1D ML prediction is performed to predict facies and porosity (or other petrophysical properties) from well log data; and (ii) the resulted in 1D predictions is upscaled and distributed using both ML and geostatistics and to perform 2D or 3D prediction without seismic data (e.g., 3D seismic cube, 2D seismic data). Python is executed to the workflow because it is open access and intuitive with many powerful libraries to carry out data analytic and various ML tasks. The exemplary libraries for ML in Python are Scikit-learn and Keras. For some of the tasks such as preparing some data, creating a base 3D grid, 1D upscaling, and mainly for geostatistics modeling, a 3D static modeling package may be used. In 1D prediction, the task identification is initiated in terms of ML activities. Facies prediction is treated as discrete property and they are handled as a classification problem or clustering problem, respectively. Special 1D unsupervised clustering, referred to as sequent hierarchical approach, for discrete property is executed and can be used as for reverse engineering. In contrast, petrophysical prediction is considered a continuous property and may be solved as part of a regression problem. For 2D or 3D task identification, spatial coordinate location features and also upscaled values at a point or grid cells are required to spatially distribute these properties. Within 1D or 3D prediction activities, commonly there are 5 main stages, starting with data preparation, then exploratory data analysis, followed by data pre-processing, after that, ML modeling, and finally ML evaluation. At the same time, 3D geostatistics is generated to be ground truth or as comparison. Innovative 3D hybrid static model is generated by combining ML and geostatistics technology.

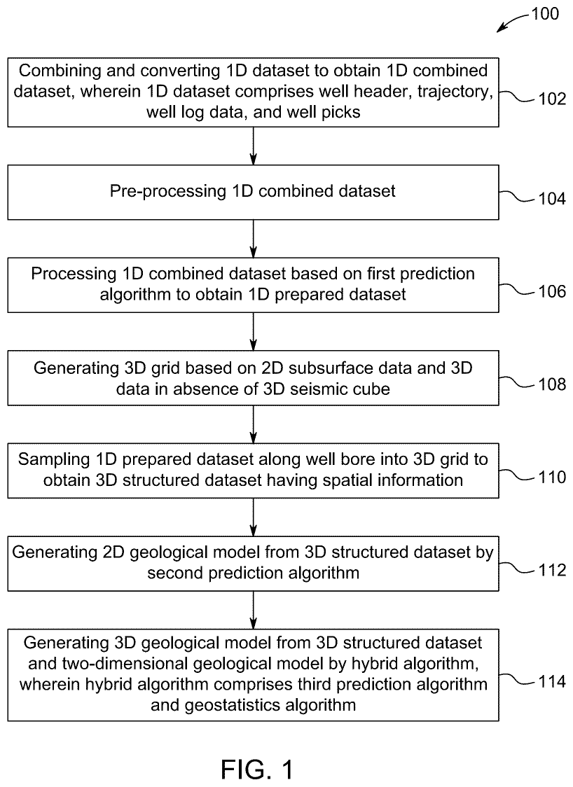

Referring to FIG. 1, illustrated is a flowchart of a computer implemented method (hereinafter simply referred to as “method,” and as represented by reference numeral 100) for an end-to-end two-dimensional (2D) and three-dimensional (3D) geological modeling. The method 100 provides an approach to geological analysis, integrating both two-dimensional and three-dimensional perspectives. By leveraging advanced techniques, the method 100 aims to provide a more comprehensive and accurate representation of geological structures, facilitating better decision-making in fields such as resource exploration and environmental studies. Herein, the end-to-end 2D and 3D geological modeling is a comprehensive process that includes the entire workflow from data collection to the generation of geological models. This way the method 100 is designed to enhance the interpretation and visualization of subsurface geological formations. It may be understood that steps 102-104 of the method 100 as described herein are only illustrative, and other alternatives can also be provided where one or more steps are added, one or more steps are removed, or one or more steps are provided in a different sequence without departing from the spirit and the scope of the present disclosure.

At step 102, the method 100 includes combining and converting a one-dimensional (1D) dataset to obtain a 1D combined dataset, in which the 1D dataset comprises well header data, trajectory data, well log data, and well pick data. This process of combining and converting the 1D dataset into the 1D combined dataset involves integrating various subsurface data elements. The “1D dataset,” in this context, refers to a collection of linear, single-dimensional data elements related to geological features. In particular, the 1D dataset includes the well header, which is a summary record containing detailed information about the well; a trajectory, detailing the path of the borehole; well log data, which are records of the geological properties encountered during drilling; and well picks, which are specific points of interest identified within the well logs. Well pick data, indicating geological zonation, play a useful role in characterizing geological features and guiding subsequent analysis.

In the step 102, the “combining” process may involve integration of these diverse sets of data into a unified format, ensuring they are compatible and can be analyzed collectively. On the other hand, the “conversion” process may involve standardization of data units, aligning data scales, and interpolating data points to create a continuous and comprehensive dataset. Specifically, these data elements, traditionally formatted in spreadsheets (like structured spreadsheets including columns and rows, which is the most common and basic format for the 1D data) or specific formats like LAS and DLIS, are combined into a coherent format, suitable for machine learning processes. This combination and conversion process is designed to unify disparate data elements into a single, coherent dataset, thus laying the groundwork for further analysis and modeling in both 2D and 3D geological contexts.

In an embodiment, the well log data is selected from the group consisting of a continuous basic log, an interpreted continuous log, an interpreted discrete log, and a combination thereof. This well log data includes a variety of types, each offering unique insights into subsurface geology. The continuous basic log refers to the primary form of well log data, continuously recorded as measurements along the wellbore, and includes essential measurements like gamma ray, resistivity, density, neutron, and sonic. The interpreted continuous log is a more processed form of the basic log, where data is analyzed and interpreted to provide insights into geological formations, providing advanced interpretations such as porosity, permeability, and saturation. The interpreted discrete log focus on specific intervals or points, providing detailed analysis at selected depths, and includes data like facies.

At step 104, the method 100 includes pre-processing the 1D combined dataset (hereinafter, sometimes, referred to as “pre-processing step 104”). This pre-processing of the 1D combined dataset is a phase where the collected raw data is refined and prepared for further analysis. This may be required as raw data often contains inconsistencies, errors, or irrelevant information that can skew or obstruct accurate modeling. The pre-processing involves cleaning the data to remove inaccuracies, normalizing data formats for consistency, and simplifying complex data into more analyzable forms. The goal is to transform the raw data into a reliable and standardized format, ensuring that the subsequent modeling and analysis are based on the most accurate and relevant information available.

In present embodiments, the pre-processing of the 1D combined dataset involves several sub-steps to prepare the data for advanced analysis. The pre-processing step 104 may start with loading the structured format data from the 1D combined dataset into machine learning (ML) platform language (e.g., python). These sub-steps collectively refine the 1D combined dataset, preparing it for machine learning processes in geological modeling.

Firstly, the pre-processing step 104 includes analyzing the 1D combined dataset with an exploratory data analysis to obtain descriptive statistics and characteristics of the well log data and a relationship within the well log data. The exploratory data analysis (EDA) may employ univariate, bivariate, and multivariate analyses. The univariate analysis focuses on individual variables to provide descriptive statistics and characteristics of the well log data, covering both input features and target variables. Bivariate and multivariate analyses are focused about the relationships between two or more variables, for understanding the complex interactions within the well log data.

Then, the pre-processing step 104 includes cleaning the 1D combined dataset to mitigate missing data or outliers. This sub-step addresses the issues of improper or ‘dirty’ well log data. The reasons for data anomalies may include acquisition challenges or borehole conditions affecting the quality of well log readings. Such issues may arise from various factors, such as the drilling operation, wireline logging conditions, or logging below casing points from previous drilling stages. For instance, well logging relies on the drilling operation, particularly during logging-while-drilling or wireline logging phases, and since these procedures are inherently influenced by the condition of the borehole, this significantly impacts the accuracy and reliability of the sensor readings in well log data. Another common possibility is due to casing reading when logging below casing point from existing previous drilling stage. Other possibilities of concerns include drilling fluid, lithology, fluid, and log processing condition. This sub-step ensures the removal or correction of these inconsistencies to improve data quality. Further, often occurring due to operational or environmental factors, missing and outlier data in well logs may need to be handled. This sub-step employs statistical methods or dedicated machine learning processes (like local outlier factor and isolation forest), based on the data type, to also address such issues.

Subsequently, the pre-processing step 104 includes rescaling and transforming the 1D combined dataset for homogeneity. Given the diverse nature and units of well log properties, rescaling may be required. This sub-step aims to standardize different units and account for variances in logging technologies or tool brands over time. Common methods include normalization and robust scaling, and this process can be performed either pre- or post-data splitting for machine learning modeling. Also, the data transformation involves adjusting the scale of well log data, which may vary between linear and logarithmic scales, to ensure consistency and appropriateness for further analysis.

Finally, the pre-processing step 104 includes executing a feature ranking. This sub-step of feature ranking or importance employs machine learning tools to identify and rank the most significant input parameters that influence the predictions made by the machine learning model. This sub-step may help with focusing on the most impactful data features in subsequent modeling processes.

At step 106, the method 100 includes processing the 1D combined dataset based on a first prediction algorithm to obtain a 1D prepared dataset (hereinafter, sometimes, referred to as “processing step 106”). The processing of the 1D combined dataset involves applying machine learning techniques to the 1D combined dataset, enabling the extraction of more refined and usable information. Herein, the “first prediction algorithm” is the initial machine learning algorithm applied to the 1D combined dataset. The objective here is to transform the initial, raw data into a format that is better suited for detailed analysis and modeling. In present embodiments, the processing step 106 involves several sub-steps to ensure that the ML model is accurately trained, evaluated, and applied for predicting geological properties from the well log data.

Firstly, the processing step 106 includes splitting the 1D combined dataset into train data, test data, and blind well data. That is, the 1D combined dataset is divided into the train data (training data) which is used to teach the ML model, the test data which is used to evaluate predictions of the ML model, and the blind well data (being completely excluded from the train data and the test data) which is used for unbiased evaluation of performance of the ML model. This splitting follows standard ML practices but includes the aspect of blind well validation. In an example, the ratio between training and test data is typically set around 80:20, 70:30, or any ratio therebetween ensuring sufficient data for learning while retaining a sufficient set for validation.

Then, the processing step 106 includes training the first prediction algorithm with the train data. Herein, the ML model is trained using the train data. This training process involves feeding the ML model with the input features (e.g., gamma ray, resistivity, density, neutron, Photoelectric Factor (PEF), and sonic log data) and the target variable (such as porosity). The ML model learns to predict the target based on these features.

Further, the processing step 106 includes evaluating the first prediction algorithm by performing a prediction with the test data. That is, once the ML model is trained, it is evaluated using the test data. This evaluation assesses how well the ML model can predict new, unseen data. This involves comparing the predictions of the ML model against actual data to assess accuracy, typically measured by correlation determination (R²). Techniques like cross plotting actual versus predicted data and overlaying well log visualizations may be used for this evaluation.

Subsequently, the processing step 106 includes tuning a first setting of the first prediction algorithm based on an evaluation. Based on the evaluation results (for instance, if the initial predictions are not satisfactory), adjustments or ‘tuning’ of settings (known as hyperparameters) of the ML model are made, typically using the train data. This process is iterative and aims to improve performance of the ML model against the test data. This process involves fine-tuning various aspects of the ML model to find the best parameters for accurate prediction.

Finally, the processing step 106 includes obtaining the 1D prepared dataset using a tuned first prediction algorithm. That is, after tuning, the algorithm is applied to the 1D combined dataset, as adjusted based on insights from the training and testing phases. This application results in the 1D prepared dataset, which is enhanced and refined, to be utilized for further modeling processes.

In present examples, different ML algorithms for the ML model may be employed depending on whether the well log data is continuous or discrete. In an embodiment, the well log data is continuous and wherein the first prediction algorithm is selected from a support vector machine, a ridge regression, an extreme gradient boosting, an artificial neural network, a deep neural network, and a long short-term memory. That is, for continuous well log data, algorithms such as Support Vector Machine (SVM), Ridge Regression, Extreme Gradient Boosting (XGBoost), Artificial Neural Network (ANN), Deep Neural Network (DNN), and Long Short-Term Memory (LSTM) are considered. The said algorithms are implemented as the first prediction algorithm as these are well suited for handling continuous data variations, such as in the present case of the well log data being continuous. In another embodiment, the well log data is discrete and wherein the first prediction algorithm is a discrete supervised prediction selected from the group consisting of a random forest, an artificial neural network, a deep neural network, and the long short-term memory. That is, conversely, when the well log data is discrete, the selection shifts to algorithms suited for discrete supervised prediction, including Random Forest, ANN, DNN, and LSTM, as these algorithms are particularly effective for categorizing and analyzing data that is not continuous but segmented into distinct classes or categories.

In the present disclosure, in the evaluation phase of the ML model, key metrics such as accuracy, F1-score, confusion matrix, and log visualization are prioritized, particularly for multiclass classification tasks like facies prediction in geology. This may be required as geological facies typically comprise more than two categories. Continuous predictions from the ML model, including petrophysical logs (e.g., porosity, permeability), are utilized to enhance discrete property predictions. Now, if performance of the ML model is subpar in the test data or the blind well data, hyperparameter tuning is employed for improvement (as discussed). In cases where predictions from the test data are accurate but performance drastically declines in the blind well data, indicating potential overfitting, a series of strategies, including hyperparameter tuning, are deployed. If these strategies fail to yield satisfactory results (e.g., accuracy, F1-score below 0.6), an alternative approach involving reverse engineering through discrete unsupervised clustering is considered. This approach aids in understanding and addressing the limitations of the supervised model in blind well scenarios. The present disclosure leverages unsupervised machine learning to create new discrete properties like facies, serving as fresh label data for supervised classification. This approach, similar to semi-supervised learning, uses the same dataset and settings that previously underperformed in supervised ML.

In embodiments of the present disclosure, the tuning step (as discussed in preceding paragraphs) involves several intricate processes. Herein, firstly, the tuning step includes clustering the 1D combined dataset with a sequent hierarchical clustering algorithm. This involves applying the sequent hierarchical clustering algorithm to the 1D combined dataset. In an example, the sequent hierarchical clustering algorithm may be k-means clustering (KMC) algorithm. The process initially focuses on differentiating basic geological structures, such as sand and shale lithology (using specific logs, e.g., gamma ray, porosity etc.), and then progressively refines these classifications in subsequent clustering sequences. Then, the tuning step includes determining a number of clusters based on an elbow method. Herein, an optimal number of clusters is determined using the elbow method. This technique involves plotting the explained variance against the number of clusters and identifying the point where the rate of decrease sharply changes, indicating an optimal balance between the number of clusters and the variance explained. Further, the tuning step includes creating a discrete unsupervised clustering. This process involves forming clusters in a manner that may not rely on predefined labels. This process may be required, especially when dealing with complex geological data where explicit categorization may not be straightforward. Subsequently, the tuning step includes evaluating the discrete unsupervised clustering. Herein, the clustering results are evaluated using metrics such as silhouette score, visual log and domain expert agreement. This assessment ensures that the clusters formed are meaningful and representative of the underlying geological structures. Further, the tuning step includes tuning a second setting of the sequent hierarchical clustering algorithm. That is, based on the evaluation, adjustments are made to settings of the clustering algorithm to optimize the clustering outcome. This may involve changing parameters that control how such clustering algorithm forms clusters. Finally, the tuning step includes integrating the discrete unsupervised clustering to the first prediction algorithm. This integration allows the first prediction algorithm to use the refined, cluster-based insights, enhancing its predictive accuracy, especially for complex geological data like facies or lithology.

At step 108, the method 100 includes generating a 3D grid based on a 2D subsurface data and a 3D data in the absence of a seismic data (e.g., 3D seismic cube, 2D seismic data). Herein, the “2D subsurface data” refers to geological information represented in two dimensions, typically including maps and cross-sections that illustrate geological features such as layers, faults, and formations from a planar perspective. Further, the “3D data” refers to spatial information about subsurface structures in three dimensions. In some embodiments, the 3D data includes, but not limited to, fault plane interpretation, three dimensional geobodies, and seismic geomorphology. This process involves the setup of the 2D subsurface data in constructing a 3D geological framework, referred to as the “3D grid”. The 3D grid is further supplemented by incorporating the 3D data, which includes detailed fault interpretations in a three-dimensional context, along with the previously prepared 1D data. Notably, this process omits the use of a traditional seismic data (e.g., 3D seismic cube, 2D seismic data), which is a volumetric dataset obtained from seismic surveys. Herein, the 2D subsurface data and the 3D data are formatted for compatibility with 3D geological modeling applications available in the market. In the present embodiments, the 3D grid itself is characterized by discretized cells, each embodying a segment of the structural geological framework. This discretization allows for a detailed and spatially accurate representation of geological features, for subsequent modeling and analysis within the confines of structure of the 3D grid.

At step 110, the method 100 includes sampling the 1D prepared dataset along a well bore into the 3D grid to obtain a 3D structured dataset having a spatial information. That is, after generating the 3D grid, the method 100 includes integrating the 1D prepared dataset within the 3D grid, a process termed as log upscaling or well blocking. This involves sampling the 1D log values along the wellbore and placing them into the 3D grid. The sampling techniques commonly employed include arithmetic, geometric, and harmonic averaging for continuous well log data, and a “most of” approach for discrete well log properties. This results in obtaining the structured 3D dataset with spatial coordinates (i,j,k), where ‘i’ and ‘j’ represent horizontal dimensions, and ‘k’ is the vertical element. Each coordinate point (i,j,k) along the wellbore is assigned sampled well log data, thus creating the 3D structured dataset with detailed spatial information. The 3D structured dataset facilitates machine learning tasks to predict geological properties across 1D to 3D spaces, using continuous log data for supervised regression tasks, and facies discrete log data for supervised classification tasks or unsupervised clustering, depending on the specific requirements.

At step 112, the method 100 includes generating a 2D geological model from the 3D structured dataset by a second prediction algorithm (hereinafter, sometimes, referred to as “generating the 2D geological model step 112”). That is, after combining 1D, 2D, and 3D data as 3D grid discretized container and bringing well log value into cells of the 3D grid along the well bore, then structured 3D data having spatial information (i,j,k) is prepared. This process of generating the 2D geological model includes analyzing the data within the 3D grid, which has been enhanced with geological information from various sources. Herein, the second prediction algorithm interprets this data to construct a two-dimensional representation of the geological features. The 2D geological model thus generated provides a detailed view of the geological structures within a specific horizontal plane of the subsurface. This helps in translating the complex, multi-dimensional data into a format that is more comprehensible and useful for geological analysis and decision-making.

In embodiments of the present disclosure, the generating the 2D geological model step 112 (as discussed in preceding paragraphs) involves several intricate processes. This process leverages algorithms like SVM, k-nearest neighbor (KNN), and Gaussian process, with hyperparameter tuning as necessary to enhance model prediction. Firstly, the generating the 2D geological model step 112 includes slicing the 3D structured dataset in a vertical layer. This process involves dividing the 3D grid into specific vertical layers, or slices, each representing a cross-section of the subsurface geology at a particular depth. Then, the generating the 2D geological model step 112 includes training the second prediction algorithm using a sliced 3D structured dataset. That is, the sliced 3D structured dataset is used to train the second prediction algorithm. This training process utilizes the spatially structured data to enable the second prediction algorithm to recognize and model geological features in two dimensions. In general, data pre-processing (e.g., rescaling, transformation) and data splitting are not needed for this kind of structured spatial data for ML. Further, the generating the 2D geological model step 112 includes evaluating the second prediction algorithm. Herein, the performance of the trained second prediction algorithm is evaluated, focusing on its accuracy in predicting geological features within the 2D space. This 2D ML spatial prediction evaluation may be attained by checking the accuracy, visual result screening, and verifying the geology features. Subsequently, the generating the 2D geological model step 112 includes tuning a third setting of the second prediction algorithm. That is, based on the evaluation results, adjustments or tuning are made to settings of the second prediction algorithm. This fine-tuning aims to enhance the accuracy and reliability of the predictions made by the second prediction algorithm. Finally, the generating the 2D geological model step 112 includes generating the 2D geological model. That is, the second prediction algorithm, once tuned, is applied to generate the 2D geological model. The 2D geological model provides a detailed representation of geological features within the specified 2D slice of the subsurface, and helps in understanding subsurface geology, for more advanced 3D modeling.

It may be understood that, although, the 2D ML facies prediction is seen as preliminary and indicative for choosing the best ML algorithm for spatial prediction, it may be noted that there is no direct correlation between 3D and 2D ML predictions. The methodology applied in 2D space is adapted to 3D space, using the full i, j, k coordinates for more comprehensive spatial analysis. This approach, however, may not always ensure that the detailed geological features, especially at the well level, are fully captured by the ML algorithm, highlighting the distinction between high accuracy and the preservation of detailed geological information.

At step 114, the method 100 includes generating a 3D geological model from the 3D structured dataset and the 2D geological model by a hybrid algorithm, wherein the hybrid algorithm comprises a third prediction algorithm and a geostatistics algorithm (hereinafter, sometimes, referred to as “generating the 3D geological model step 114”). As discussed in the preceding paragraphs, the 3D structured dataset represents the subsurface geological features organized within the 3D grid, thus providing a comprehensive and spatially accurate representation of the subsurface geology. Further, the 2D geological model represents geological features in two dimensions, including maps or cross-sections of subsurface structures. Herein, the hybrid algorithm leverages machine learning for spatial prediction in both 2D and 3D spaces using the 3D structured dataset and the 2D geological model. The hybrid algorithm uniquely combines the third prediction algorithm with the geostatistics algorithm. The geostatistics part, especially important in representing discrete geological properties, complements predictive power of the hybrid algorithm by providing a realistic geological framework. This combination enables the generation of the 3D geological model that predicts geological properties accurately, specifically enabling accuracy enhancement in reservoir parameter prediction, while considering geological realities like facies proportions and well data consistency.

As used herein, in an embodiment, the third prediction algorithm is selected from the group consisting of a support vector machine (SVM), a k-nearest neighbor (KNN), and a gaussian process. Each algorithm offers a unique approach to modeling complex geological phenomena. In particular, the SVM is effective for finding the optimal boundary between data classes, the KNN for pattern recognition based on proximity, and the gaussian process for probabilistic predictions considering uncertainties. Further, the geostatistics algorithm is a sequential indicator simulation (SIS). It may be contemplated that industrial standard of properties population in 3D space is geostatistics. The SIS, a standard in geostatistical modeling, is implemented for populating properties in 3D space. The SIS relies on variography, especially the interpretation of horizontal variograms, which can be complex due to less frequent spatial data compared to vertical variograms. The SIS, used for discrete properties, incorporates variogram analysis and facies proportion. The SIS algorithm is flexible enough to integrate other data types, enhancing the overall accuracy of the generated model. The SIS generally considers well data and facies proportion in its outputs, although it can sometimes produce random, pixelized facies patterns without a clear trend.

The integration of the third prediction algorithm (ML facies predictions) with the SIS creates the hybrid model (as discussed), combines the strengths of ML and geostatistics. This hybrid model is evaluated for facies proportion, well consistency, and visual trends in 3D space. This approach leads to a more comprehensive model, facilitating advanced petrophysical modeling constrained by the hybrid facies.

In particular, the generating the 3D geological model step 114 (as discussed in preceding paragraphs) involves several intricate processes. Firstly, the generating the 3D geological model step 114 includes training the third prediction algorithm using the 3D structured dataset. That is, the third prediction algorithm, chosen from techniques like the SVM, the KNN, or the gaussian process, is trained using the 3D structured dataset. This training is performed for the third prediction algorithm to accurately interpret and model the complex geological features present in the 3D space. Then, the generating the 3D geological model step 114 includes evaluating the third prediction algorithm. That is, post-training, the third prediction algorithm is evaluated to assess its accuracy and effectiveness in modeling geological structures within the 3D space. Such evaluation process may be contemplated, as discussed for preceding steps. Further, the generating the 3D geological model step 114 includes tuning a fourth setting of the third prediction algorithm. Herein, based on evaluation outcomes, the settings of the third prediction algorithm are fine-tuned to optimize the corresponding ML model for more accurate predictions of geological features. Next, the generating the 3D geological model step 114 includes generating a 3D facies trend by the third prediction algorithm. Utilizing the tuned prediction algorithm, the 3D facies trend is generated, which reflects the distribution and characteristics of different rock types within the geological structure. Subsequently, the generating the 3D geological model step 114 includes integrating the 3D facies trend into the geostatistics algorithm to create the hybrid algorithm. That is, the 3D facies trend is then integrated into the geostatistics algorithm, typically the sequential indicator simulation, for enhancing reliability and accuracy of the geostatistics algorithm, particularly in representing facies proportions and variogram interpretations. Further, the generating the 3D geological model step 114 includes evaluating the hybrid algorithm. This is done to evaluate the combined strength of machine learning and geostatistics, ensuring the hybrid algorithm accurately represents geological structures, maintains facies proportion, and considers the well data. Finally, the generating the 3D geological model step 114 includes generating the 3D geological model based on the hybrid algorithm, wherein the 3D geological model is constrained by a hybrid facies. The 3D geological model offers an enhanced prediction of reservoir parameters, as its predictions are guided by the combined insights from both machine learning and geostatistics, leading to a more comprehensive and accurate representation of the geological features.

In some embodiments, the well log data includes a geological facies and a measured petrophysical property and wherein a first 3D geological model of the geological facies is generated before a second 3D geological model of the measured petrophysical property. Herein, the “geological facies” refer to distinct rock units with specific characteristics and attributes, representing different depositional environments or conditions in geology, and the “measured petrophysical property” represents quantifiable properties of rocks, such as porosity, permeability, and saturation. In the present method 100, initially, the first 3D geological model of the geological facies is generated using ML and geostatistical algorithms, such as SIS, as discussed. This first 3D geological model, termed as the hybrid facies model, integrates ML facies predictions as a secondary property, and its evaluation includes assessing facies proportion, well data consistency, and visual trends. Once the hybrid facies model is established, the process advances to petrophysical modeling, which is influenced by the hybrid facies framework, to generate the second 3D geological model of the measured petrophysical property. The porosity property, driven by geological facies, is modeled first as it significantly influences other petrophysical properties like permeability and saturation. This sequential approach ensures that the geological complexity is accurately represented in the models.

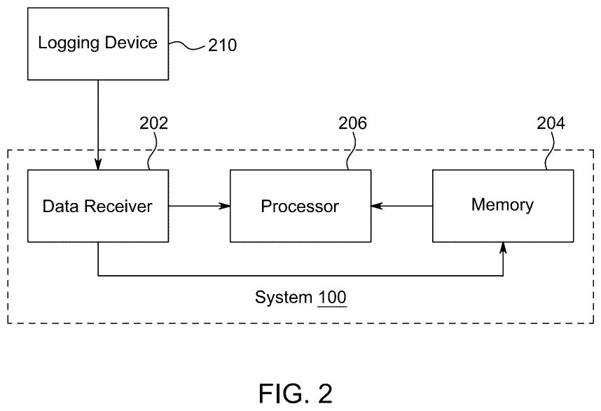

Referring to FIG. 2, illustrated is a block diagram of a system (as represented by reference numeral 200) for the end-to-end two-dimensional (2D) and three-dimensional (3D) geological modeling. Various embodiments and variants disclosed above, with respect to the aforementioned method 100 apply in the same manner to the system 200. In general, the system 200 is designed with an integrated configuration for geological modeling, incorporating hardware and software components working in unison. In particular, as illustrated, the system 200 includes a data receiver 202, a memory 204, and a processor 206, all interconnected to enable seamless data flow and processing. Further, the system 200 is in data communication with a logging device 210. In the exemplary illustration, the logging device 210 is shown separate from the system 200; however, in other examples, the logging device 210 may be part of the system 200 without departing from the spirit and the scope of the present disclosure.

In the system 200, the logging device 210 may be a field instrument used in the collection of subsurface geological data. The logging device 210 may typically include sensors and data recording systems that capture well log data, as required for the modeling process. The data receiver 202 is a component which serves as the interface between the logging device 210 and the memory 204 and/or the processor 206, structured to capture and relay the log data. The data receiver 202 may be configured to ensure integrity of the log data for processing, in the system 200. The memory 204 is a storage component within the system 200, and store program instructions to be executed by the processor 206. The processor 206, in itself, is a central computing unit coupled to the memory and 204 the data receiver 202, and executes the program instructions stored in memory 204. The processor 206 processes the incoming 1D data, synthesizes 2D and 3D models, and applies predictive algorithms, to provide core functions of the system 200.

In the system 200, the data receiver 202 is configured to collect the 1D data from the logging device 210. The processor 206 is configured to receive the 1D data from the data receiver 202 wherein the 1D dataset comprises the well header, the trajectory, the well log data, and the well picks. The processor 206 is further configured to execute the program instruction as stored in the memory 204. Herein, the program instruction includes combining and converting the 1D dataset to obtain the 1D combined dataset. The program instruction further includes pre-processing the 1D combined dataset. The program instruction further includes processing the 1D combined dataset based on the first prediction algorithm to obtain the 1D prepared dataset. The program instruction further includes processing the 1D combined dataset based on the first prediction algorithm to obtain the 1D prepared dataset. The program instruction further includes generating the 3D grid based on the 2D subsurface data and the 3D data in the absence of the seismic data (e.g., 3D seismic cube, 2D seismic data). The program instruction further includes sampling the 1D prepared dataset along the well bore into the 3D grid to obtain the 3D structured dataset having the spatial information. The program instruction further includes generating the 2D geological model from the 3D structured dataset by the second prediction algorithm. The program instruction further includes generating the 3D geological model from the 3D structured dataset and the 2D geological model by the hybrid algorithm, wherein the hybrid algorithm comprises the third prediction algorithm and the geostatistics algorithm. The details for executing these program instructions have been discussed in the preceding paragraphs, and thus not repeated herein for brevity of the present disclosure.

In one or more embodiments of the system 200, the well log data is continuous. Herein, the first prediction algorithm is selected from the support vector machine, the ridge regression, the extreme gradient boosting, the artificial neural network, the deep neural network, and the long short-term memory. In one or more embodiments of the system 200, the well log data is discrete. Herein, the first prediction algorithm is the discrete supervised prediction selected from the group consisting of the random forest, the artificial neural network, the deep neural network, and the long short-term memory. These details have been discussed in the preceding paragraphs, and thus not repeated herein for brevity of the present disclosure.

In one or more embodiments of the system 200, the pre-processing step further comprises: analyzing the 1D combined dataset with the exploratory data analysis to obtain descriptive statistics and characteristics of the well log data and the relationship within the well log data; cleaning the 1D combined dataset to mitigate missing data or outliers; rescaling and transforming the 1D combined dataset for homogeneity; and executing the feature ranking. In one or more embodiments of the system 200, the processing step further comprises: splitting the 1D combined dataset into train data, test data, and blind well data; training the first prediction algorithm with the train data; evaluating the first prediction algorithm by performing the prediction with the test data; tuning the first setting of the first prediction algorithm based on the evaluation; and obtaining the 1D prepared dataset using the tuned first prediction algorithm. In one or more embodiments of the system 200, the tuning step further comprises: clustering the 1D combined dataset with the sequent hierarchical clustering algorithm; determining the number of clusters based on the elbow method; creating the discrete unsupervised clustering; evaluating the discrete unsupervised clustering; tuning the second setting of the sequent hierarchical clustering algorithm; and integrating the discrete unsupervised clustering to the first prediction algorithm. In one or more embodiments of the system 200, the generating the 2D geological model step further comprises: slicing the 3D structured dataset in the vertical layer; training the second prediction algorithm using the sliced 3D structured dataset; evaluating the second prediction algorithm; tuning the third setting of the second prediction algorithm; and generating the 2D geological model. In one or more embodiments of the system 200, the generating the 3D geological model step further comprises: training the third prediction algorithm using the 3D structured dataset; evaluating the third prediction algorithm; tuning the fourth setting of the third prediction algorithm; generating the 3D facies trend by the third prediction algorithm; integrating the 3D facies trend into the geostatistics algorithm to create the hybrid algorithm; evaluating the hybrid algorithm; and generating the 3D geological model based on the hybrid algorithm. Herein, the 3D geological model is constrained by the hybrid facies. Again, the details for executing the program instructions to perform these steps have been discussed in the preceding paragraphs, and thus not repeated herein for brevity of the present disclosure.

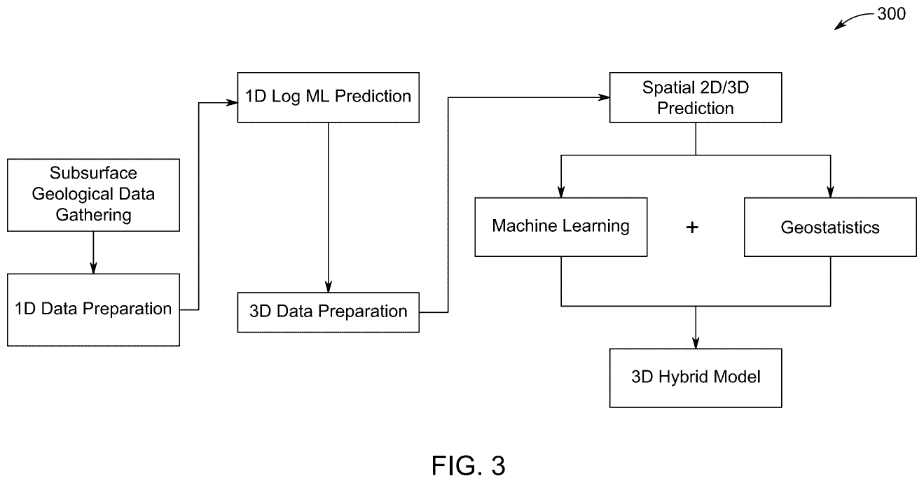

Referring to FIG. 3, illustrated is an end-to-end workflow (as represented by reference numeral 300) for predicting subsurface geological structures, transitioning from one-dimensional (1D) to three-dimensional (3D) data. As illustrated, the workflow 300 includes an initial set-up phase involving the establishment of a geological data ecosystem for subsurface geological data gathering, with subsequent preparation of 1D data serving as the groundwork. Following this, the workflow 300 engages machine learning algorithms to predict or cluster well log data to compensate for any missing information. The workflow 300 then advances to preparation of three-dimensional (3D) data, where 3D data preparation includes creating the 3D grid as a data repository with spatial attributes. Subsequently, the workflow 300 extracts 2D spatial predictions from the 3D grid, which informs and enhances 3D machine learning predictions. The workflow 300 concludes with the integration of ML and geostatistics to construct an advanced 3D hybrid geological model.

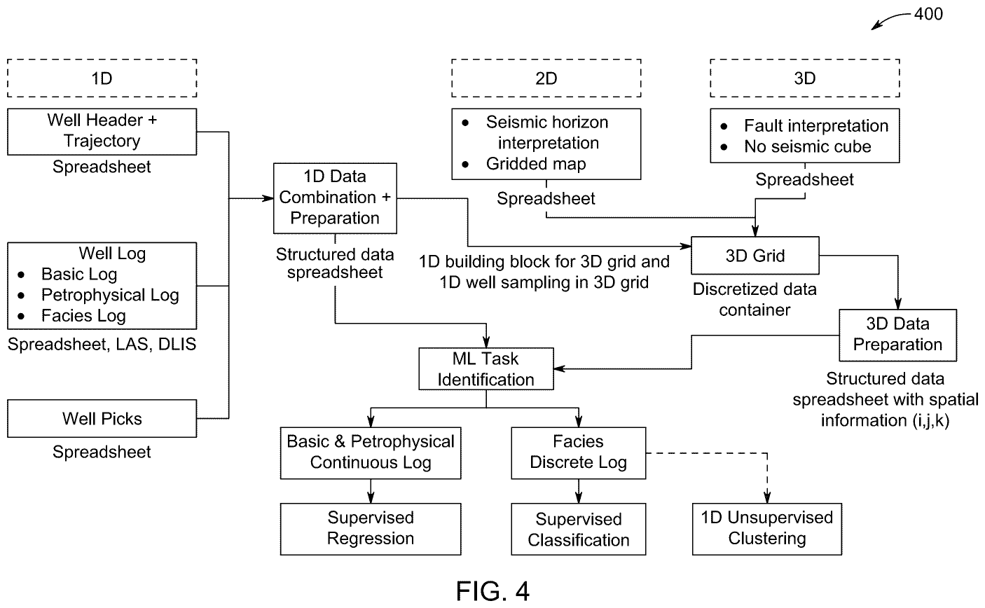

Referring now to FIG. 4, illustrated is a workflow (as represented by reference numeral 400) for a preparatory phase for machine learning (ML) in geological modeling. The workflow 400 is configured for collection and organization of subsurface data. The workflow 400 initiates by 1D dataset that may include well header and trajectory, well log data that may contain continuous basic log (e.g., gamma ray, resistivity, density, neutron, sonic etc.), interpreted continuous log (e.g., porosity, permeability, saturation), interpreted discrete log (e.g., facies), and well picks. Well picks that indicate geological zonation is utilized to determine the geological characteristic and to constrain the analysis later. Well header and trajectory, well log and well picks are normally formatted as spreadsheet. Well logs most of the time have their own format such as LAS, DLIS. The workflow 400, then, involves combining all of the 1D data to prepare specific readable format for ML processes. The most common and basic format for 1D data is structured spreadsheets that include columns and raw as normal spreadsheets. The workflow 400 further involves setting-up 2D subsurface data, where this dataset is used to make the 3D container, referred to as 3D grid along with 3D data such as seismic horizon (fault) interpretation in 3D space and 1D data. In the workflow 400, seismic data (e.g., 3D seismic cube, 2D seismic data) is not used. These 2D and 3D datasets are prepared in specific format for importing in 3D geological model application available in the market. The 3D grid is discretized cells that have structural geological framework on it.

Further, in the workflow 400, after the 3D grid is available, 1D log data is placed in the 3D grid by sampling the value of 1D log along the well bore into the 3D grid. This sampling is known as log upscaling or well blocking. The most common sampling is an averaging method that mainly consists of arithmetic, geometric, and harmonic averaging for continuous well log data and “most of” for discrete well log property. Having the 3D grid with sampled well log data, structured spreadsheet data with spatial information in 3D space (i,j,k) can be generated where each specific dedicated i,j,k along the well bore have sampled well log data in 3D space. In i,j,k 3D space, it may be noted that i and j normally refer to horizontal dimension elements, where k is vertical element. Further in the workflow 400, ML task identification may be established using 1D data and/or 3D data (as prepared). Herein, the workflow 400 involves predicting subsurface geological properties in 1D to 3D space, therefore basic and interpreted petrophysical logs are considered as continuous data, and, on the other hand, interpreted facies log is considered as discrete data. The continuous log data is modelled using supervised regression task in ML. Facies discrete log may be resolved with supervised classification task and or unsupervised clustering when the data is conditioned for such task. Thereby, the workflow 400 sets the stage for ML tasks (as discussed in the proceeding paragraphs).

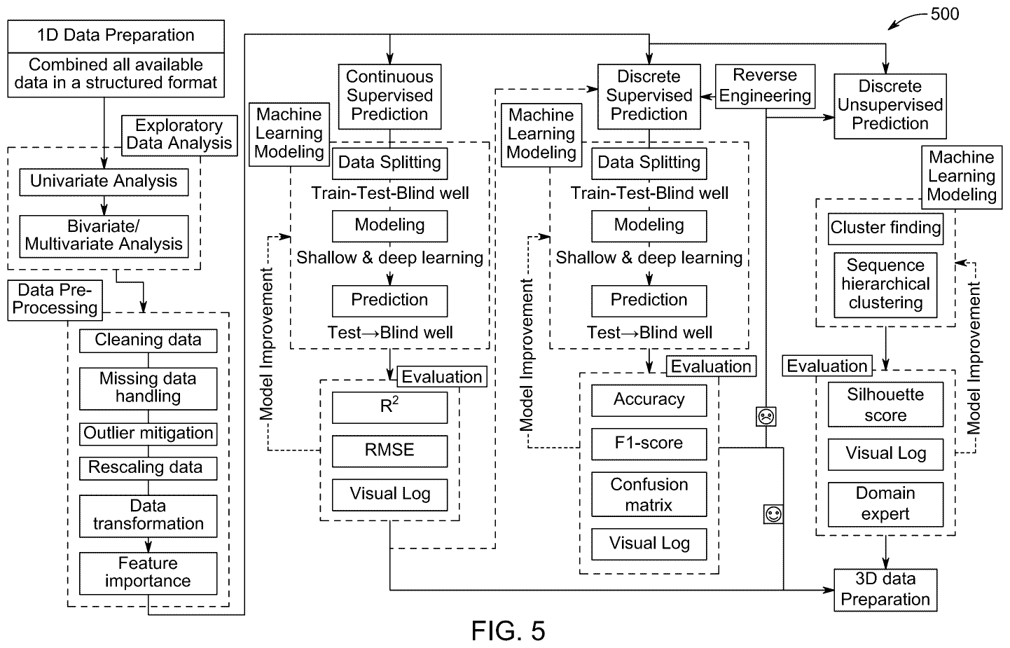

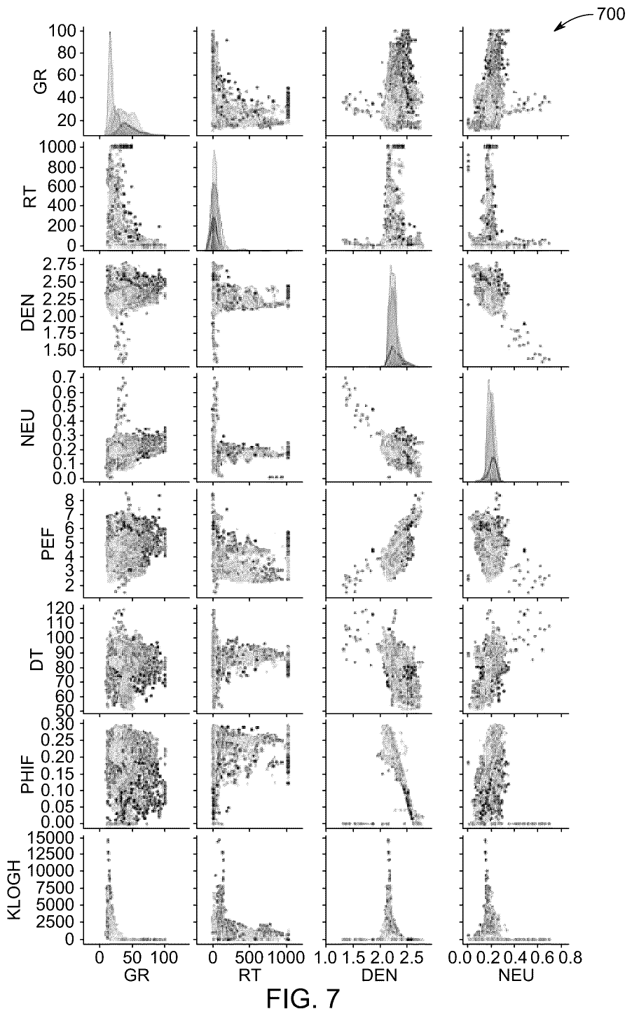

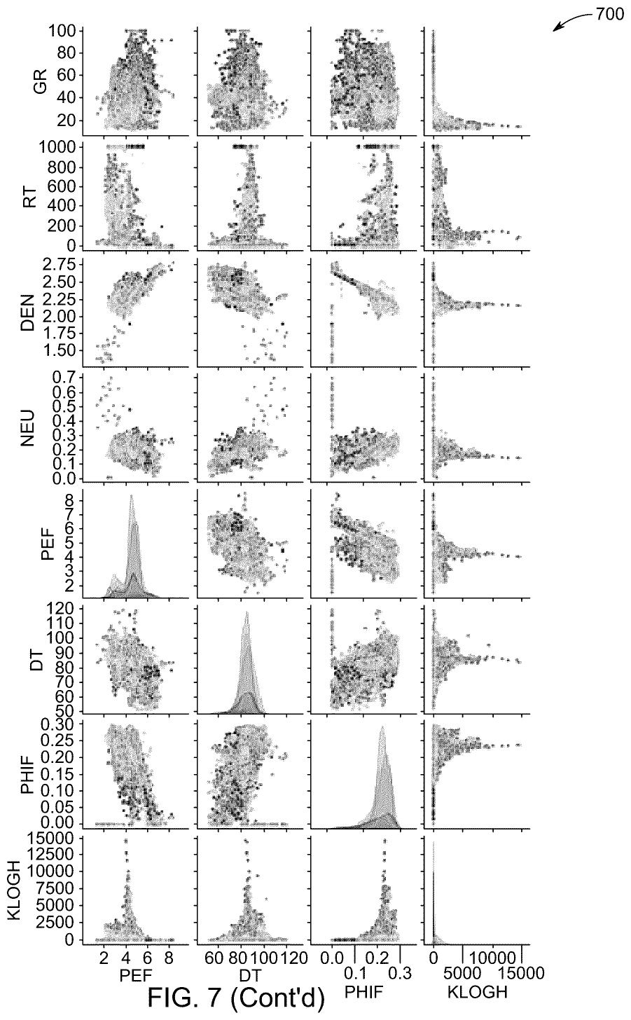

Referring now to FIG. 5, illustrated is a workflow (as represented by reference numeral 500) for 1D ML well log prediction. The workflow 500 initiates with import of the structured format data from 1D data preparation into ML platform language (e.g., python). The workflow 500 then, implements Exploratory data analysis (EDA) for all chains of ML. FIG. 7 illustrates a matrix for EDA (as represented by reference numeral 700), depicting scatter plots to visualize relationships and distributions of multiple variables in a dataset. Each plot is coded corresponding to different facies or other categorical geological properties. The variables such as GR (Gamma Ray), RT (Resistivity), DEN (Density), NEU (Neutron), PEF (Photoelectric Effect Factor), DT (Delta Time), PHIF (Porosity from Fluid), and KLOGH (Permeability from Log-H), are standard well log measurements used in geology and reservoir engineering to characterize subsurface formations. Herein, EDA includes univariate and bivariate/multivariate analysis. Univariate analysis, as suggested by its name, involves one variable, provides the descriptive statistics and characteristics of the well log data covering the input features and target. On the other hand, bivariate analysis involves 2 variables analysis, whereas multivariate analysis involves more than 2 variables, that may explain the relationship between 2 or more variables.

Referring back to FIG. 5, the workflow 500, using all aspects of raw data through the EDA, executes data pre-processing. Cleaning data is a fundamental process in this stage where well log data could be improper or dirty. This cleaning data step leads to other data pre-processing steps such as resolving missing and outlier data. Missing and outlier in the well log data could be due to acquisition or the borehole condition. Well logging relies on the drilling operation where logging is run while drilling, or wire condition when running wireline logging, where both of these relate to the hole condition and impact the sensor reading of well log. The common possibility is also due to casing reading when logging is run below casing point from existing previous drilling stage. Other possibilities of these concerns include drilling fluid, lithology, fluid, and log processing condition. These missing and outlier well log data may be handled and mitigated either with statistics or dedicated ML (e.g., local outlier factor, isolation forest) when the data condition is supported to do so. Rescaling data is another one of the important processes in geological well log data. Each well log property has its own nature unit, and different units may exist between different well log data. Moreover, the logging year acquisition related to the logging technology, further exacerbated by different brand of logging tools, make the well log data non-homogeneous. Normalization (with respect to the minimum or maximum) and standard or robust scaling are the common rescaling method. Rescaling may be performed before machine learning modeling and/or after data splitting. The workflow 500 may also involve data transformation which relates to the scaling of the well log data and can be implemented where most of the well log data is in linear scale but there may be some well log data with logarithmic scale. Further, the workflow 500 may involve feature importance or feature ranking using dedicated ML, which could be executed to the supervised ML to unravel and illustrate the most significant input parameters influencing the prediction of the ML.

Following data pre-processing, the workflow 500 implements ML model. In the workflow 500, as per the ML task identification, both task either continuous log supervised prediction or discrete supervised prediction/classification not only undergo data splitting as per standard ML procedure but also well data splitting approach is adapted for blind well validation, and hence the use of train data, test data, and blind well data. Input feature and target are already arranged during ML task identification, for example, porosity supervised prediction with input features including of all of basic log data (e.g., gamma ray, resistivity, density, neutron, PEF, and sonic log). Full blind well data are exclusively excluded from the train data and the test data, where the ratio of the train data to test data could be 80:20,70:30, or any ratio therebetween. The workflow 500 subsequently involves performing ML modeling after data splitting. Vary ML algorithms may be implemented during modeling, that may include shallow learning and deep learning in the train data. For 1D continuous well log data, such as basic log density and neutron or interpreted petrophysical log such as porosity, ML algorithms are preferably support vector machine (SVM), ridge regression, extra gradient boosting (XGboost), artificial neural network, deep neural network, and long short-term memory (LSTM). Once ML model is trained using the train data, the first prediction may be made for the test data. With prediction for the test data, the workflow 500 may involve evaluation on this data that mainly consist of correlation determination (R²) by cross plotting (actual vs prediction data) and also overlaying well log visualization between actual and prediction. If the result of the well log prediction is not satisfying, hyperparameter tuning may be performed using the train dataset, and the ML model is again implemented for prediction for the test dataset and ultimately to blind well dataset to improve and optimize the ML model.

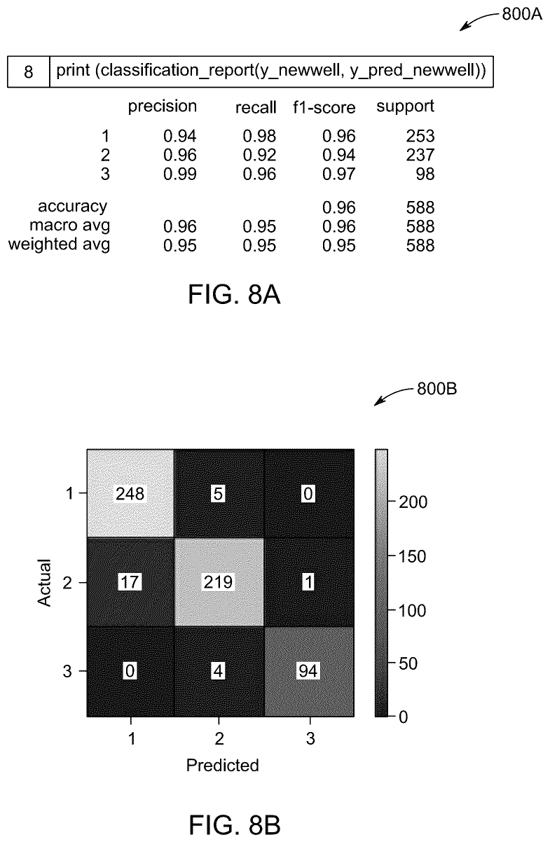

In the workflow 500, for 1D discrete well log data, random forest, artificial neural network, deep neural network, and LSTM are relevant algorithms. Herein, evaluation of the ML model may emphasize on accuracy, f1-score, confusion matrix, and log visualization, where these evaluations are appropriate for multiclass classification task such as facies prediction in geology (since geological facies are generally more than 2 facies). FIGS. 8A-8C illustrate the evaluation metrics and predictions for a machine learning model in facies classification. Specifically, FIG. 8A depicts a table 800A which shows precision, recall, f1-score, and support for each facies class, along with overall accuracy and macro averages, indicating a high-performing model. Further, FIG. 8B depicts a confusion matrix 800B which visualizes performance of the ML model, with most predictions aligning with actual classifications, as seen by the high numbers along the diagonal. Moreover, FIG. 8C depicts a bar graph 800C which compares actual and predicted facies at various depths, with each color in the gradient representing a different facies class, and demonstrating how well predictions made by the model correspond to the actual data.

Referring back to FIG. 5, in the workflow 500, the resulting 1D continuous prediction such as petrophysical log (e.g., porosity, permeability) in addition to basic logs may be used to improve the discrete property prediction. If the result is very poor in test or even in blind well, the model improvement through hyperparameter tuning may need to be performed. In another case, where there are good predictions in test data but the performance drops significantly in blind well data, overfitting model can be referred. When hyperparameter tuning and all strategies to overcome overfitting model (discrete data lumping, avoiding data leakage, with or without rescaling data, imbalanced dataset mitigation, class weight procedure) may not result in good predictions (e.g., accuracy, f1-score less than 0.6), reverse engineering by creating discrete unsupervised clustering may alternatively be implemented. This proposal alternative helps in resolving, verifying, and explaining the poor performance of the existing supervised model in blind well. Further, in the workflow 500, new discrete property (e.g., facies) from unsupervised ML is used as new label data or target for discrete supervised classification. During unsupervised ML modeling, the same well data set may be used to replicate same setting of previous poorly supervised machine learning train, test, and blind well data. When the prediction shows good performance, this alternative proposal can confirm the issue in the original discrete labels. This method of reverse engineering may be considered as semi-supervised ML.

Further, for the workflow 500, in unsupervised clustering, the same input features as supervised approach are used. The most optimum cluster may be found by generating elbow method and calculating silhouette score. As in geology domain, specifically in clastic lithology, the clustering of discrete properties may be improved by implementing sequent hierarchical clustering, preferably k-means clustering (KMC) algorithm. The specific logs (e.g., gamma ray, porosity etc.) that indicate lithology may be used first to differentiate the general sand and shale lithology in the 1st sequent clustering. Optimum clustering may need to be achieved in this 1st sequence. Having the 1st sequence result, the 2nd sequence clustering may be deployed into one of specific result of the 1st cluster (for example sand cluster). This 2nd clustering will differentiate in detail the sand quality. The input data for the 2nd clustering can be similar to the 1st sequence, but it is recommended to add more input data. Further clustering may be done until the result is realistic. In the workflow 500, the evaluation of unsupervised clustering result may be evaluated using silhouette score, visual log, and domain expert agreement. Similar to supervised ML, this unsupervised sequence hierarchical clustering may be improved geologically by changing the algorithm settings. When the results are acceptable, either with original supervised classification or with sequence hierarchical approach, then the workflow 500 involves bring the 1D log data to spatial modeling by preparing 3D data from the 3D grid.

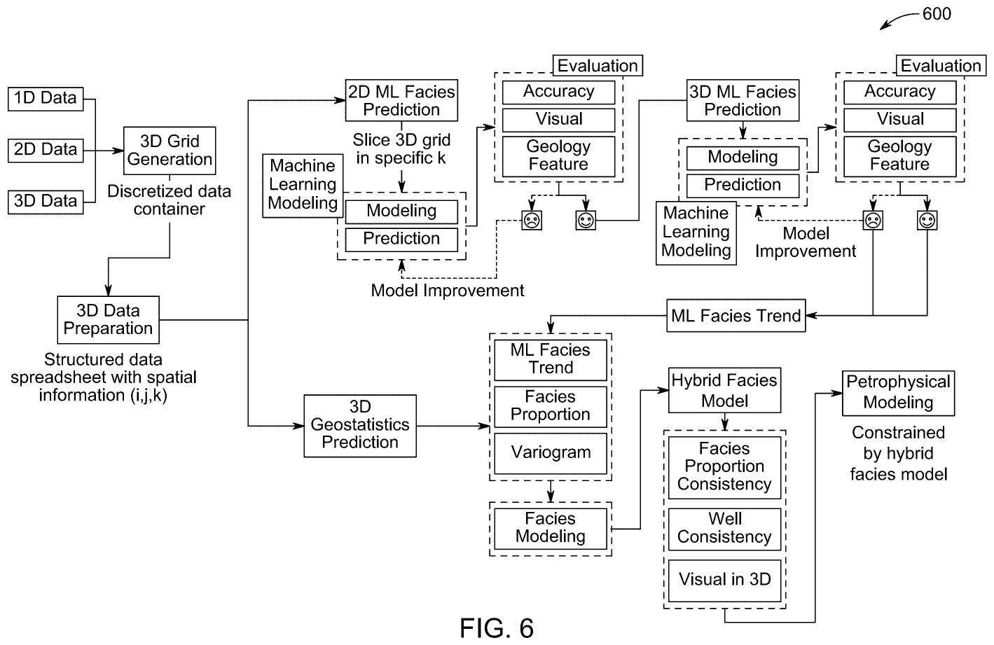

Referring now to FIG. 6, illustrated is a workflow (as represented by reference numeral 600) for 2D or 3D ML spatial prediction. The workflow 600 initiates with combining 1D, 2D, and 3D data as 3D grid discretized container and bringing well log value into 3D grid cells along the well bore. The workflow 600, then, involves preparing structured 3D data having spatial information i, j, k. The workflow 600 further involves 2D ML facies prediction which may be achieved by slicing 3D grid in specific k (vertical layer). In general, data pre-processing (e.g., rescaling, transformation) and data splitting are not needed for this kind of structured spatial data for ML. For this purpose, the recommended base case model algorithms are SVM, k-nearest neighbor (KNN), and the gaussian process. To enhance model prediction, the workflow 600 involves applying hyperparameter tuning. Herein, such 2D ML spatial prediction evaluation may be attained by checking accuracy, visual result screening, and verifying details of the geology features.

In the workflow 600, 2D ML facies prediction may be considered as preliminary result for 3D ML facies prediction. This enables indicating the best ML algorithm for spatial prediction even though there is no direct relationship between 3D and 2D ML prediction. Similar methodology as used for 2D prediction for 2D space, is applied onto 3D space where full i, j, k is used. Spatial facies ML prediction is a valuable tool to derive plausible facies trend in 2D and 3D spaces since ML is a data driven approach. However, the high accuracy does not mean that the detailed geology is preserved. It may be noted that sometimes data at well level along the well is not considered by ML algorithm. In particular, industrial standard of properties population in 3D space is geostatistics. Geostatistics modeling is a model-driven technique that heavily depends on variography. Horizontal variogram interpretation is not straightforward since data in spatial dimension is not as frequent as vertical variogram. Preferably, the geostatistics algorithm for discrete properties is sequential indicator simulation (SIS) where this algorithm has flexibility to be combined with other data. Geostatistics simulation algorithm main building blocks include variogram and facies proportion. Most of the time, SIS results consider well data and facies proportion; however on some occasions, geostatistical modeling may exhibit random fuzzy pixelized facies where there is no trend conserved.

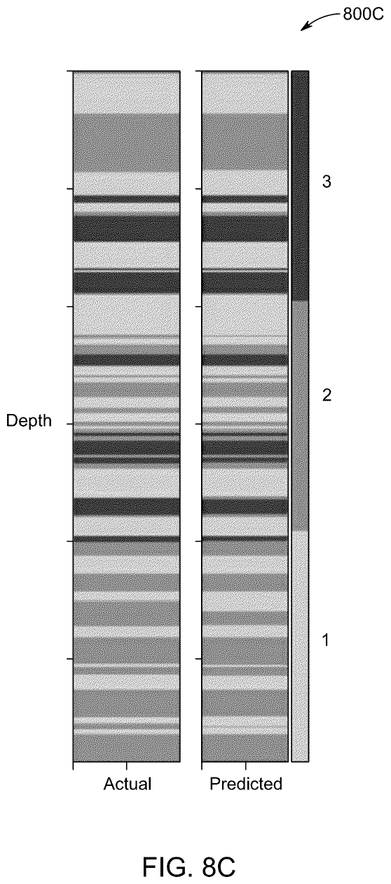

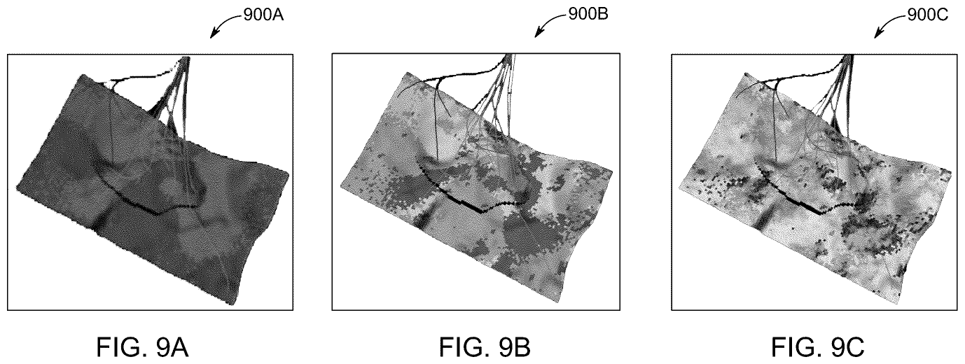

FIGS. 9A-9C provide a novel hybrid approach to 3D geological modeling, which integrates machine learning (ML) with geostatistics, to overcome the above discussed issue of non-conservation of trends. As depicted in FIG. 9A (providing image 900A), this approach uses Support Vector Machine (SVM) ML trend for understanding facies distribution. Further, as depicted in FIG. 9B (providing image 900B), this approach uses Sequential Indicator Simulation (SIS) combined with ML to identify facies trends. Furthermore, as depicted in FIG. 9C (providing image 900C), this approach uses Sequential Gaussian Simulation (SGS), constrained to facies, for modeling porosity. The said approach, in general, utilizes three different stages: SVM ML trend identification, integration of SIS with ML predictions, and the application of SGS for porosity modeling, all displayed at a specific geological layer in FIGS. 9A-9C.

Referring back to FIG. 6, continuing from previous description, the workflow 600 subsequently involves proposing 3D facies hybrid model by reconciling the best part of each of ML and geostatistics into one model, based on the strengths and the limitations of ML and geostatistics algorithms. The resulted ML facies prediction is treated as 3D facies trend property or secondary property (for each facies available), that is integrated within SIS. Hybrid facies model evaluation is conducted by checking facies proportion, well consistency, and visual trend inspection in 3D space. Once the 3D hybrid facies model is settled, the next step of petrophysical modeling constrained by hybrid facies may be executed. Porosity property that is driven by geological facies may be run first since this property may affect the remaining petrophysical properties such as permeability and saturation. The workflow 600 thereby concludes.

The method 100 and the system 200 of the present disclosure represent a significant advancement in the field of geological modeling, addressing the challenge of accurately predicting subsurface geological properties. Traditional methods rely heavily on seismic data, which can be expensive and limited in resolution. By utilizing well log data, which is often more readily available, the present disclosure provides a cost-effective alternative to traditional seismic-based methods. The present disclosure introduces a hybrid approach combining machine learning and geostatistics. By using ML algorithms on well log data, it predicts properties like facies and porosity, which are then upscaled for 2D or 3D modeling. The integration of ML with geostatistics enhances accuracy and overcomes limitations of data scarcity and quality. The detailed models generated can lead to better decision-making in resource exploration and extraction, ultimately reducing risks and costs associated with these activities. The present disclosure has applications for resource exploration and extraction, environmental studies, and geotechnical engineering.

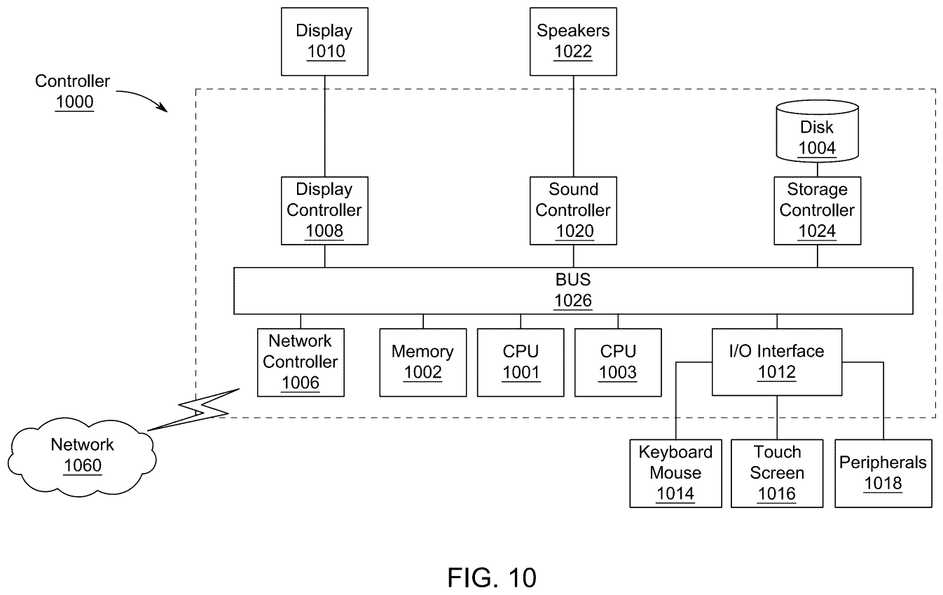

Next, further details of the hardware description of the computing environment according to exemplary embodiments is described with reference to FIG. 10. In FIG. 10, a controller 1000 is described as representative of the system 200 of FIG. 2 in which the controller is a computing device which includes a CPU 1001 which performs the processes described above/below. The process data and instructions may be stored in memory 1002. These processes and instructions may also be stored on a storage medium disk 1004 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 1001, 1003 and an operating system such as Microsoft Windows 7, Microsoft Windows 10, Microsoft Windows 11, UNIX, Solaris, LINUX, Apple MAC-OS, and other systems known to those skilled in the art.

The hardware elements in order to achieve the computing device may be realized by various circuitry elements, known to those skilled in the art. For example, CPU 1001 or CPU 1003 may be a Xenon or Core processor from Intel of America or an Opteron processor from AMD of America, or may be other processor types that would be recognized by one of ordinary skill in the art. Alternatively, the CPU 1001, 1003 may be implemented on an FPGA, ASIC, PLD or using discrete logic circuits, as one of ordinary skill in the art would recognize. Further, CPU 1001, 1003 may be implemented as multiple processors cooperatively working in parallel to perform the instructions of the inventive processes described above.

The computing device in FIG. 10 also includes a network controller 1006, such as an Intel Ethernet PRO network interface card from Intel Corporation of America, for interfacing with network 1060. As can be appreciated, the network 1060 can be a public network, such as the Internet, or a private network such as an LAN or WAN network, or any combination thereof and can also include PSTN or ISDN sub-networks. The network 1060 can also be wired, such as an Ethernet network, or can be wireless such as a cellular network including EDGE, 3G, 4G and 5G wireless cellular systems. The wireless network can also be WiFi, Bluetooth, or any other wireless form of communication that is known.

The computing device further includes a display controller 1008, such as a NVIDIA GeForce GTX or Quadro graphics adaptor from NVIDIA Corporation of America for interfacing with display 1010, such as a Hewlett Packard HPL2445w LCD monitor. A general purpose I/O interface 1012 interfaces with a keyboard and/or mouse 1014 as well as a touch screen panel 1016 on or separate from display 1010. General purpose I/O interface also connects to a variety of peripherals 1018 including printers and scanners, such as an OfficeJet or DeskJet from Hewlett Packard.

A sound controller 1020 is also provided in the computing device such as Sound Blaster X-Fi Titanium from Creative, to interface with speakers/microphone 1022 thereby providing sounds and/or music.

The general purpose storage controller 1024 connects the storage medium disk 1004 with communication bus 1026, which may be an ISA, EISA, VESA, PCI, or similar, for interconnecting all of the components of the computing device. A description of the general features and functionality of the display 1010, keyboard and/or mouse 1014, as well as the display controller 1008, storage controller 1024, network controller 1006, sound controller 1020, and general purpose I/O interface 1012 is omitted herein for brevity as these features are known.

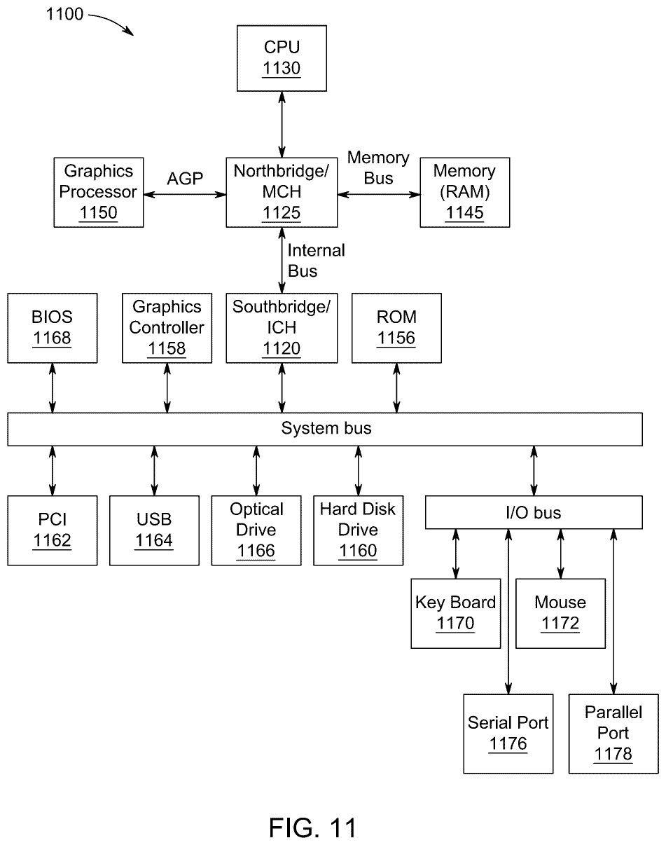

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 11.

FIG. 11 shows a schematic diagram of a data processing system, according to certain embodiments, for performing the functions of the exemplary embodiments. The data processing system is an example of a computer in which code or instructions implementing the processes of the illustrative embodiments may be located.

In FIG. 11, data processing system 1100 employs a hub architecture including a north bridge and memory controller hub (NB/MCH) 1125 and a south bridge and input/output (I/O) controller hub (SB/ICH) 1120. The central processing unit (CPU) 1130 is connected to NB/MCH 1125. The NB/MCH 1125 also connects to the memory 1145 via a memory bus, and connects to the graphics processor 1150 via an accelerated graphics port (AGP). The NB/MCH 1125 also connects to the SB/ICH 1120 via an internal bus (e.g., a unified media interface or a direct media interface). The CPU Processing unit 1130 may contain one or more processors and even may be implemented using one or more heterogeneous processor systems.

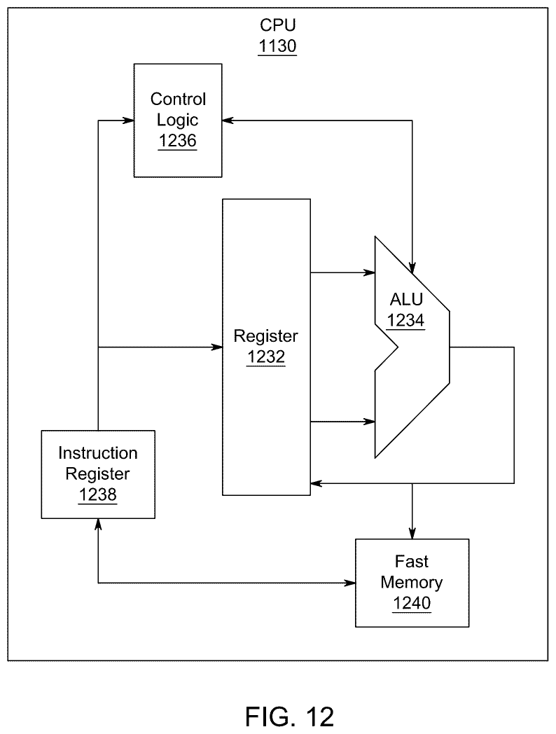

For example, FIG. 12 shows one implementation of CPU 1130. In one implementation, the instruction register 1238 retrieves instructions from the fast memory 1240. At least part of these instructions are fetched from the instruction register 1238 by the control logic 1236 and interpreted according to the instruction set architecture of the CPU 1130. Part of the instructions can also be directed to the register 1232. In one implementation the instructions are decoded according to a hardwired method, and in another implementation the instructions are decoded according a microprogram that translates instructions into sets of CPU configuration signals that are applied sequentially over multiple clock pulses. After fetching and decoding the instructions, the instructions are executed using the arithmetic logic unit (ALU) 1234 that loads values from the register 1232 and performs logical and mathematical operations on the loaded values according to the instructions. The results from these operations can be feedback into the register and/or stored in the fast memory 1240. According to certain implementations, the instruction set architecture of the CPU 1130 can use a reduced instruction set architecture, a complex instruction set architecture, a vector processor architecture, a very large instruction word architecture. Furthermore, the CPU 1130 can be based on the Von Neuman model or the Harvard model. The CPU 1130 can be a digital signal processor, an FPGA, an ASIC, a PLA, a PLD, or a CPLD. Further, the CPU 1130 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 11, the data processing system 1100 can include that the SB/ICH 1120 is coupled through a system bus to an I/O Bus, a read only memory (ROM) 1156, universal serial bus (USB) port 1164, a flash binary input/output system (BIOS) 1168, and a graphics controller 1158. PCI/PCIe devices can also be coupled to SB/ICH 1188 through a PCI bus 1162.

The PCI devices may include, for example, Ethernet adapters, add-in cards, and PC cards for notebook computers. The Hard disk drive 1160 and CD-ROM 1166 can use, for example, an integrated drive electronics (IDE) or serial advanced technology attachment (SATA) interface. In one implementation the I/O bus can include a super I/O (SIO) device.

Further, the hard disk drive (HDD) 1160 and optical drive 1166 can also be coupled to the SB/ICH 1120 through a system bus. In one implementation, a keyboard 1170, a mouse 1172, a parallel port 1178, and a serial port 1176 can be connected to the system bus through the I/O bus. Other peripherals and devices that can be connected to the SB/ICH 1120 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry, or based on the requirements of the intended back-up load to be powered.

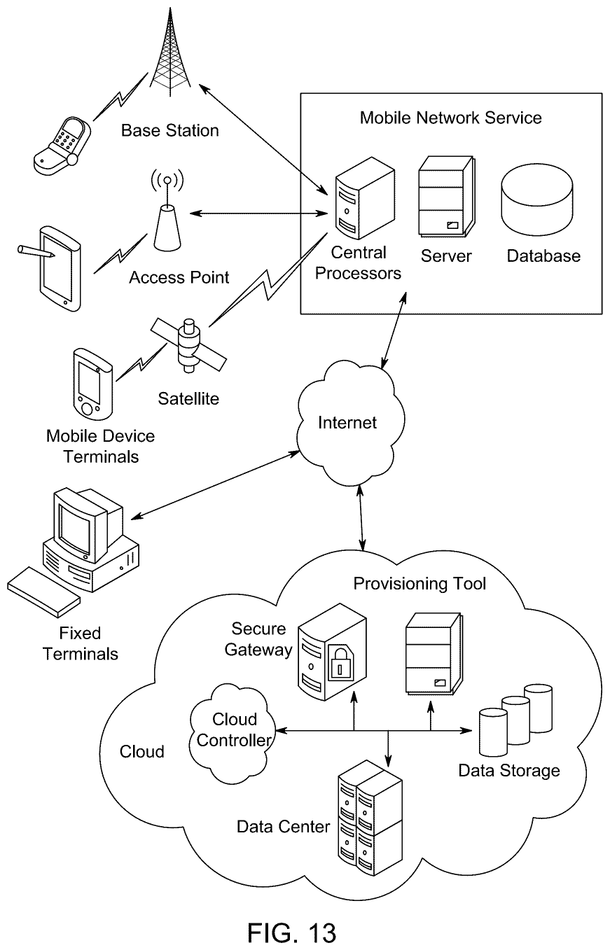

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 13, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A computer implemented method for an end-to-end two-dimensional (2D) and three-dimensional (3D) geological modeling, comprising:
processing a plurality of one-dimensional (1D) datasets to obtain a 1D combined dataset, wherein the plurality of 1D datasets includes well header data, trajectory data, well log data, and well pick data;
pre-processing the 1D combined dataset;
processing the 1D combined dataset based on a first prediction algorithm to obtain a 1D prepared dataset;
generating a 3D grid based on 2D subsurface data and 3D data in the absence of a seismic data;
sampling the 1D prepared dataset along a well bore into the 3D grid to obtain a 3D structured dataset having spatial information;
generating a 2D geological model from the 3D structured dataset by a second prediction algorithm; and
generating a 3D geological model from the 3D structured dataset and the 2D geological model by a hybrid algorithm, wherein the hybrid algorithm comprises a third prediction algorithm and a geostatistics algorithm.

2. The method of claim 1, wherein the well log data is selected from the group consisting of a continuous basic log, an interpreted continuous log, an interpreted discrete log, and a combination thereof.

3. The method of claim 2, wherein the pre-processing comprises:
analyzing the 1D combined dataset with an exploratory data analysis to obtain descriptive statistics and characteristics of the well log data and a relationship within the well log data;
cleaning the 1D combined dataset to mitigate missing data or outliers;
rescaling and transforming the 1D combined dataset for homogeneity; and
executing a feature ranking.

4. The method of claim 3, wherein the processing further comprises:
splitting the 1D combined dataset into train data, test data, and blind well data;
training the first prediction algorithm with the train data;
evaluating the first prediction algorithm by performing a prediction with the test data;
tuning a first setting of the first prediction algorithm based on an evaluation; and
obtaining the 1D prepared dataset using a tuned first prediction algorithm.

5. The method of claim 4, wherein the well log data is continuous and wherein the first prediction algorithm is selected from the group consisting of a support vector machine, a ridge regression, an extreme gradient boosting, an artificial neural network, a deep neural network, and a long short-term memory.

6. The method of claim 4, wherein the well log data is discrete and wherein the first prediction algorithm is a discrete supervised prediction selected from the group consisting of a random forest, an artificial neural network, a deep neural network, and the long short-term memory.

7. The method of claim 6, wherein the tuning further comprises:
clustering the 1D combined dataset with a sequent hierarchical clustering algorithm;
determining a number of clusters based on an elbow method;
creating a discrete unsupervised clustering;
evaluating the discrete unsupervised clustering;
tuning a second setting of the sequent hierarchical clustering algorithm; and
integrating the discrete unsupervised clustering to the first prediction algorithm.

8. The method of claim 4, wherein the generating the 2D geological model further comprises:
slicing the 3D structured dataset in a vertical layer;
training the second prediction algorithm using a sliced 3D structured dataset;
evaluating the second prediction algorithm;
tuning a third setting of the second prediction algorithm; and
generating the 2D geological model.

9. The method of claim 8, wherein the generating the 3D geological model further comprises:
training the third prediction algorithm using the 3D structured dataset;
evaluating the third prediction algorithm;
tuning a fourth setting of the third prediction algorithm;
generating a 3D facies trend by the third prediction algorithm;
integrating the 3D facies trend into the geostatistics algorithm to create the hybrid algorithm;
evaluating the hybrid algorithm; and
generating the 3D geological model based on the hybrid algorithm, wherein the 3D geological model is constrained by a hybrid facies.

10. The method of claim 9, wherein the third prediction algorithm is selected from the group consisting of a support vector machine, a k-nearest neighbor, and a gaussian process.

11. The method of claim 9, wherein the geostatistics algorithm is a sequential indicator simulation.

12. The method of claim 2, wherein the well log data includes a geological facies and a measured petrophysical property and wherein a first 3D geological model of the geological facies is generated before a second 3D geological model of the measured petrophysical property.

13. A system for an end-to-end two-dimensional (2D) and three-dimensional (3D) geological modeling comprising:
a data receiver configured to collect a one-dimensional (1D) data, a 2D subsurface data, and a 3D data from a logging device;
a memory to store a program instruction; and
a processor coupled to the memory and the data receiver, wherein the processor is configured to:
receive the 1D data from the data receiver wherein the 1D dataset comprises well header data, trajectory data, well log data, and well pick data; and
execute the program instruction, wherein the program instruction comprises:
combining and converting the 1D dataset to obtain a 1D combined dataset;
pre-processing the 1D combined dataset;
processing the 1D combined dataset based on a first prediction algorithm to obtain a 1D prepared dataset;
generating a 3D grid based on the 2D subsurface data and the 3D data in the absence of a seismic data;
sampling the 1D prepared dataset along a well bore into the 3D grid to obtain a 3D structured dataset having a spatial information;
generating a 2D geological model from the 3D structured dataset by a second prediction algorithm; and
generating a 3D geological model from the 3D structured dataset and the 2D geological model by a hybrid algorithm, wherein the hybrid algorithm comprises a third prediction algorithm and a geostatistics algorithm.

14. The system of claim 13, wherein the pre-processing further comprises:
analyzing the 1D combined dataset with an exploratory data analysis to obtain descriptive statistics and characteristics of the well log data and a relationship within the well log data;
cleaning the 1D combined dataset to mitigate missing data or outliers;
rescaling and transforming the 1D combined dataset for homogeneity; and
executing a feature ranking.

15. The system of claim 14, wherein the processing further comprises:
splitting the 1D combined dataset into train data, test data, and blind well data;
training the first prediction algorithm with the train data;
evaluating the first prediction algorithm by performing a prediction with the test data;
tuning a first setting of the first prediction algorithm based on an evaluation; and
obtaining the 1D prepared dataset using a tuned first prediction algorithm.

16. The system of claim 15, wherein the well log data is continuous and wherein the first prediction algorithm is selected from the group consisting of a support vector machine, a ridge regression, an extreme gradient boosting, an artificial neural network, a deep neural network, and a long short-term memory.

17. The system of claim 15, wherein the well log data is discrete and wherein the first prediction algorithm is a discrete supervised prediction selected from the group consisting of a random forest, an artificial neural network, a deep neural network, and the long short-term memory.

18. The system of claim 17, wherein the tuning further comprises:
clustering the 1D combined dataset with a sequent hierarchical clustering algorithm;
determining a number of clusters based on an elbow method;
creating a discrete unsupervised clustering;
evaluating the discrete unsupervised clustering;
tuning a second setting of the sequent hierarchical clustering algorithm; and
integrating the discrete unsupervised clustering to the first prediction algorithm.

19. The system of claim 15, wherein the generating the 2D geological model further comprises:
slicing the 3D structured dataset in a vertical layer;
training the second prediction algorithm using a sliced 3D structured dataset;
evaluating the second prediction algorithm;
tuning a third setting of the second prediction algorithm; and
generating the 2D geological model.

20. The system of claim 19, wherein the generating the 3D geological model further comprises:
training the third prediction algorithm using the 3D structured dataset;
evaluating the third prediction algorithm;
tuning a fourth setting of the third prediction algorithm;
generating a 3D facies trend by the third prediction algorithm;
integrating the 3D facies trend into the geostatistics algorithm to create the hybrid algorithm;
evaluating the hybrid algorithm; and
generating the 3D geological model based on the hybrid algorithm, wherein the 3D geological model is constrained by a hybrid facies.
